(19) United States
(12) Patent Application Publication
(10) Pub. No.: US 2025/0113718 A1
(43) Pub. Date: Apr. 3, 2025

(54) CYCLIC PEALD/PECVD THIN FILM ENCAPSULATION BARRIER

(71) Applicant: Applied Materials, Inc., Santa Clara, CA (US)

(72) Inventors: Wenhui LI, Santa Clara, CA (US); Kevin CHEN, Santa Clara, CA (US); Wen-Hao WU, San Jose, CA (US); Yu-Min WANG, Santa Clara, CA (US); Zongkai WU, Santa Clara, CA (US); Kwang Soo HUH, Palo Alto, CA (US); Lai ZHAO, Campbell, CA (US)

(21) Appl. No.: 18/907,141

(22) Filed: Oct. 4, 2024

Related U.S. Application Data
(63) Continuation of application No. PCT/US2024/048499, filed on Sep. 26, 2024.
(60) Provisional application No. 63/586,303, filed on Sep. 28, 2023.

(51) Int. Cl. H10K 59/80; C23C 16/34; C23C 16/455; C23C 16/50

(52) U.S. Cl. CPC H10K 59/873; C23C 16/345; C23C 16/45536; C23C 16/50

(57) ABSTRACT

Embodiments described herein relate to an optical device and methods of forming an optical device. The optical device includes a substrate, an illumination source, a capping layer, an encapsulation layer, and a passivation layer. The encapsulation layer includes a first atomic layer deposition (ALD) layer, a chemical vapor deposition (CVD) layer, and a second ALD layer. The method includes disposing a capping layer over an illumination layer, the illumination layer disposed over a substrate in a processing chamber; disposing a first atomic layer deposition (ALD) layer over the capping layer; disposing a chemical vapor deposition (CVD) layer over the first ALD layer; disposing a second ALD layer over the CVD layer; and disposing a passivation layer over the second ALD layer.

### CROSS-REFERENCE TO RELATED APPLICATIONS

This application claims benefit of PCT Application No: PCT/US2024/048499, filed Sep. 26, 2024 (Attorney Docket No. 44022859WO01), which claims benefit of U.S. provisional patent application Ser. No. 63/586,303, filed Sep. 28, 2023, all of which is incorporated by reference in its entirety.

### BACKGROUND

### Field

Embodiments of the present disclosure generally relate to the field of semiconductor device manufacturing. In particular, the disclosure relates to encapsulation layers and methods of forming encapsulation layers.

### Description of the Related Art

Optical devices often have displays such as liquid crystal displays (LCDs) organic light emitting-diode (OLED) displays, and quantum dot (QD) displays. Such displays can be fragile and sensitive to moisture, pressure, or particle contamination. To prevent damage to the underlying illumination source, an encapsulation layer is disposed over the illumination source to prevent damage. The inclusion of an encapsulation layer with high thickness, however, may hinder the optical device with respect to device brightness and color definition. Further, the encapsulation layer may require multiple chambers for fabrication, leading to decreased throughput.

Therefore, there is a need for improved encapsulation layers and methods of forming encapsulation layers that have a reduced thickness and increased throughput.

### SUMMARY

In one embodiment, an optical device is disclosed. The optical device includes a substrate, an illumination source, a capping layer, an encapsulation layer, and a passivation layer. The encapsulation layer includes a first atomic layer deposition (ALD) layer, a chemical vapor deposition (CVD) layer, and a second ALD layer.

In another embodiment, a method is disclosed. The method includes disposing a capping layer over an illumination layer. The illumination layer is disposed over a substrate in a processing chamber. A first atomic layer deposition (ALD) layer is disposed over the capping layer. A chemical vapor deposition (CVD) layer is disposed over the first ALD layer. A second ALD layer is disposed over the CVD layer. A passivation layer is disposed over the second ALD layer.

In yet another embodiment, an optical device is disclosed. The optical device includes a substrate, an illumination source, a capping layer, a first passivation layer, a polymer layer, and an encapsulation layer. The encapsulation layer includes a second passivation layer, and an active matrix organic light emitting diode (AMOLED) layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic view of a cluster processing system, according to embodiments.

FIG. 2 is a schematic cross-sectional view of a processing chamber, according to embodiments.

FIG. 3 is a cross sectional view of an optical device, according to embodiments.

FIG. 4 is a flow diagram of a method of forming an optical device, according to embodiments.

FIG. 5A-5E are schematic, cross sectional views of a portion of an optical device during a method of forming the optical device, according to embodiments.

FIG. 6 is a schematic, cross sectional view of a flexible optical device, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to the field of semiconductor device manufacturing. In particular, the disclosure relates to thin film encapsulation barriers and methods of forming thin film encapsulation barriers.

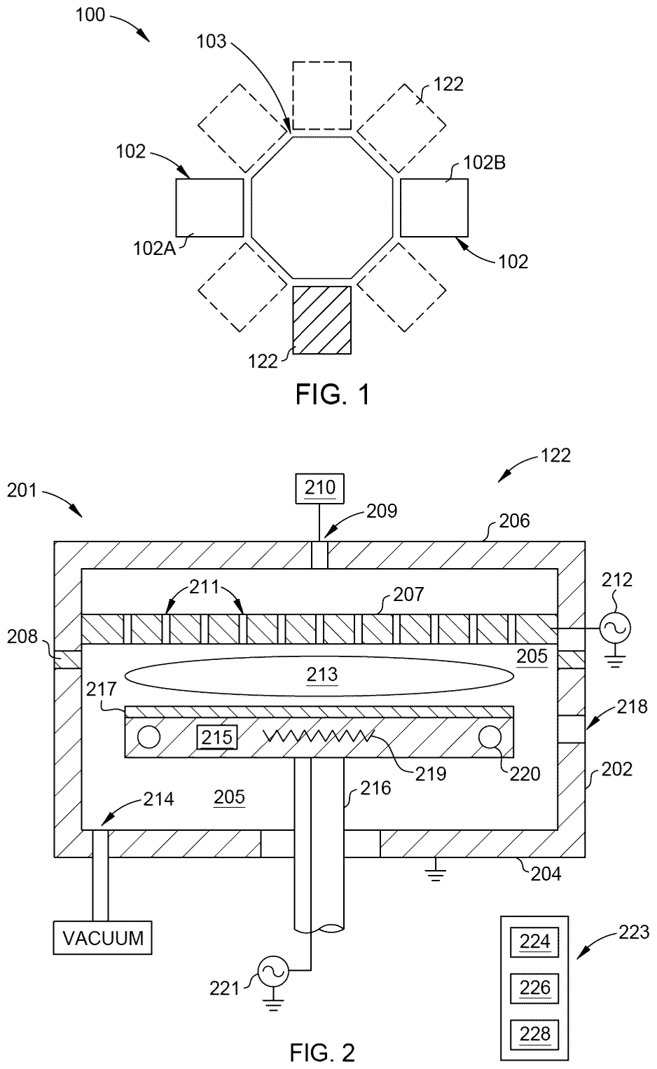

FIG. 1 is a schematic view of a cluster processing system 100. The cluster processing system 100 includes a processing platform 103, a factory interface 102, and at least one processing chamber 122. The factory interface 102 may include an input interface 102A and an output interface 102B. The factory interface 102 may include at least one docking station. At least one factory interface robot in the processing platform 103 may be configured to facilitate transfer of substrates. The input interface 102A is configured to receive one or more a substrates. The factory interface robot is configured to transfer the one or more substrates to the processing chambers 122 from the input interface 102A, and to transfer the one or more substrates from the processing chamber 122 to the output interface 102B. The output interface 102B is configured to release the one or more substrates from the cluster processing system 100.

In one embodiment of the cluster processing system 100, the cluster processing system 100 may include one or more processing chambers 122. The processing chamber 122 may be a deposition chamber (e.g., physical vapor deposition (PVD) chamber, chemical vapor deposition (CVD) chamber, plasma enhanced chemical vapor deposition (PECVD) chamber, atomic layer deposition (ALD) chamber, plasma enhanced atomic layer deposition (PEALD) chamber, or other deposition chambers), annealing chamber (e.g., high pressure annealing chamber, rapid thermal processing (RTP) chamber, or laser anneal chamber), etch chamber, cleaning chamber, pre-cleaning chamber, curing chamber, lithographic exposure chamber, or other similar type of semiconductor processing chamber. The processing chamber 122 may be configured to perform more than one semiconductor processing process, e.g., the processing chamber 122 may perform both PEALD and PECVD.

FIG. 2 is a schematic cross-sectional view of a processing chamber 122. The processing chamber 122 is configured to ignite and maintain a plasma of a plasma gas through capacitive coupling. The processing chamber 122 includes a chamber lid assembly 201, one or more sidewalls 202, and a chamber base 204. The chamber lid assembly 201 includes a chamber lid 206, a showerhead 207 disposed in the chamber lid 206, and an electrically insulating ring 208, disposed between the chamber lid 206 and the one or more sidewalls 202. The showerhead 207, the one or more sidewalls 202, and the chamber base 204 together define a processing volume 205. A gas inlet 209, disposed through the chamber lid 206 is fluidly coupled to a gas source 210. The gas source 210 may provide plasma gases, precursor gases, carrier gases, or purge gases. The showerhead 207, having a plurality of openings 211 disposed therethrough, can be used to uniformly distribute the gases from the gas source 210 into the processing volume 205. The showerhead 207 is electrically coupled to a first power supply 212, such as an RF power supply, which supplies power to ignite and maintain a plasma 213 of the processing gas through capacitive coupling therewith. Herein, the RF power has a frequency of from about 400 kHz to about 40 MHz, for example about 400 kHz to about 13.56 MHz. In other embodiments, the processing chamber 122 comprises an inductive plasma generator, and the plasma is formed through inductively coupling an RF power to the plasma gas.

The processing volume 205 is fluidly coupled to a vacuum source, such as to one or more dedicated vacuum pumps, through a vacuum outlet 214, which maintains the processing volume 205 at sub-atmospheric conditions and evacuates the processing gas and other gases therefrom. A substrate support 215, disposed in the processing volume 205, is disposed on a movable support shaft 216 sealingly extending through the chamber base 204, such as being surrounded by bellows (not shown) in the region below the chamber base 204. Herein, the processing chamber 122 is configured to facilitate transferring of a substrate 217 to and from the substrate support 215 through an opening 218 in one of the one or more sidewalls 202, which can be sealed with a door or a valve (not shown) during substrate processing.

The substrate 217, disposed on the substrate support 215, is maintained at a desired processing temperature using one or both of a heater, such as a resistive heating element 219, and one or more cooling channels 220 disposed in the substrate support 215. The one or more cooling channels 220 are fluidly coupled to a coolant source (not shown), such as a modified water source having relatively high electrical resistance or a refrigerant source. In at least one embodiment, the substrate support 215 or one or more electrodes thereof is electrically coupled to a second power supply 221, which supplies a bias voltage thereto. The temperature of the substrate 217 and the substrate support 215 is maintained at less than about 100° C. in the processing chamber 122, such as about 60° C. to about 90° C. The substrate 217 may be spaced apart from the showerhead 207 by about 650 mm to about 1200 mm.

The processing chamber 122 further includes a system controller 223 which is used to control the operation of the processing chamber 122 and implement the methods set forth herein. The system controller 223 includes a programmable central processing unit, herein the central processing unit (CPU) 224, that is operable with a memory 226 (e.g., non-volatile memory) and support circuits 228. The support circuits 228 are coupled to the CPU 224 and include cache, clock circuits, input/output subsystems, power supplies, and combinations thereof coupled to the various components of the processing chamber 122, to facilitate control thereof. The CPU 224 is one of any form of general purpose computer processor, such as a programmable logic controller (PLC), for controlling various components and sub-processors of the processing chamber 122. The memory 226, coupled to the CPU 224, is non-transitory and is typically one or more of readily available memories such as random access memory (RAM), read only memory (ROM), floppy disk drive, hard disk, or any other form of digital storage, local or remote.

Typically, the memory 226 is in the form of a computer-readable storage media containing instructions (e.g., non-volatile memory) that, when executed by the CPU 224, facilitates the operation of the processing chamber 122. The instructions in the memory 226 are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

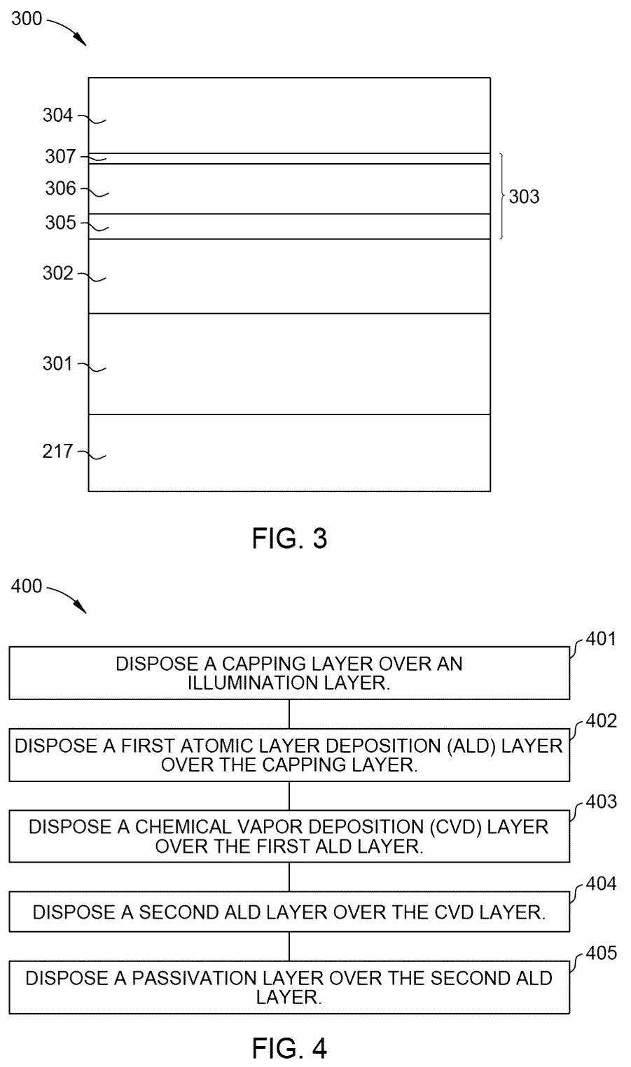

FIG. 3 is a cross sectional view of an optical device 300. The optical device 300 may be a liquid crystal display (LCD), organic light emitting-diode (OLED) display, or quantum dot (QD) display. The optical device 300 includes an illumination source 301, a capping layer 302, an encapsulation layer 303, and a passivation layer 304. The illumination source 301 may be disposed over the substrate 217. The illumination source 301 may be an OLED, a liquid crystal disposed over a backlight, or a quantum dot (QD). A QD may be configured to be an illumination source 301, or may manipulate light from an illumination source 301 that the QD is disposed over, such as an OLED or a backlight.

The capping layer 302 has a thickness of about 600 Å to about 1000 Å. The capping layer 302 may include organic materials, such as Tris(8-hydroxyquinolinato)aluminium (ALq₃), a hole-transporting layer (HTLs), an electron injection layer (EILs), a hole injection layer (HIL), or combinations thereof.

The encapsulation layer 303 includes a first atomic layer deposition (ALD) layer 305, a chemical vapor deposition (CVD) layer 306, and a second ALD layer 307. The encapsulation layer 303 has a thickness of less than about 1 μm. The first ALD layer 305 has a thickness of less than about 50 Å. The CVD layer 306 has a thickness less than about 1 μm. The second ALD layer 307 has a thickness of less than about 10 Å. The thickness of the encapsulation layer 303 being less than about 1 μm may reduce the color cross-talk of the illumination source 301, increasing the color definition of the optical device 300.

In some embodiments, the first ALD layer 305 and second ALD layer 307 have an elemental composition of about 38% to about 60% nitrogen (N), about 39% to about 50% silicon (Si), and about 5% to about 17% hydrogen (H). The N/Si ratio for the first ALD layer 305 and second ALD layer 307 is about 0.6 to about 1.5. The first ALD layer 305 and second ALD layer 307 have a refractive index at 633 nm of about 1.7 to about 2.1. The CVD layer 306 has an elemental composition of about 42% to about 46% nitrogen (N), about 54% to about 58% silicon (Si), and about 27% to about 35% hydrogen (H). The N/Si ratio for the CVD layer 306 is about 0.7 to about 0.9. The CVD layer 306 has a refractive index at 633 nm of about 1.6 to about 2.1.

The encapsulation layer 303 has a refractive index greater than about 1.8, such as about 1.85 to 2.1. The high refractive index may reduce the layer to layer reflection, increasing the brightness of optical device 300.

The thickness of the encapsulation layer 303 being less than about 1 μm further allows for more conformal deposition of the encapsulation layer 303, decreasing the non-uniformity percentage (NU %) of the encapsulation layer 303. The NU % is the variation in thickness across the encapsulation layer 303. The NU % of the encapsulation layer 303 is about 3% to about 5%. The conformity and NU % of the encapsulation layer 303 may decrease the number of seamlines in the encapsulation layer 303. The encapsulation layer 303 has a water vapor transmission rate (WVTR) of less than about 5×10⁻⁵ g/m²/day. A decrease in the number of seamlines may result in an increase in the ability of the encapsulation layer 303 to protect the illumination source from contaminants, such as water vapor.

The encapsulation layer 303 has a stress of about −1000 MPa to about 300 MPa. The difference in stress (Δ Stress) is less than about 50 MPa from the center of the substrate 217 to the edge of the substrate 217. The reduction in the Δ Stress across the substrate 217 may be due to the increased conformity, decreased NU %, and a decrease in seamlines.

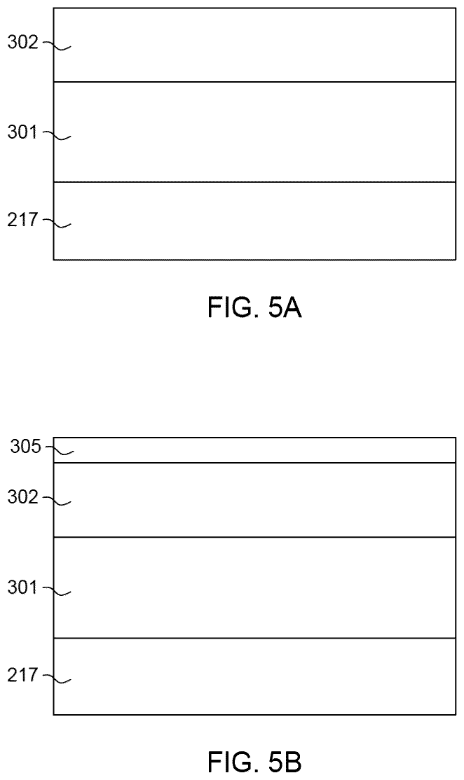

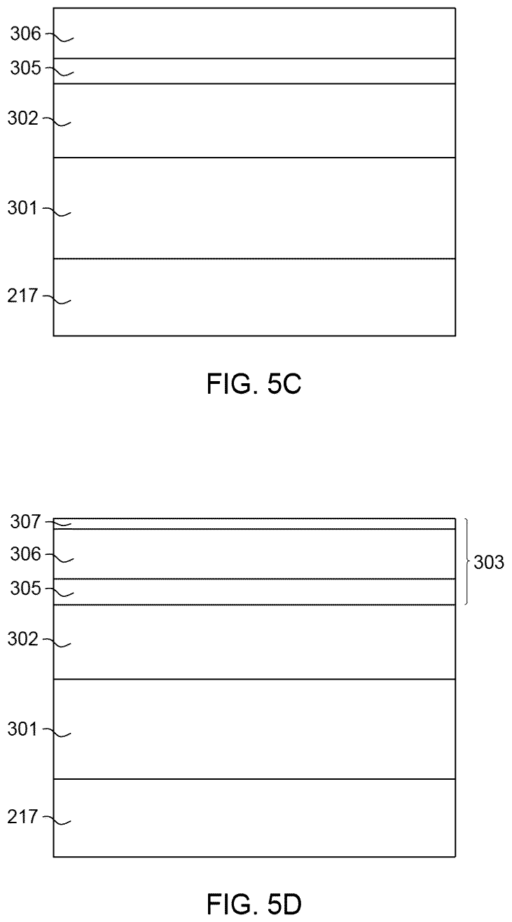

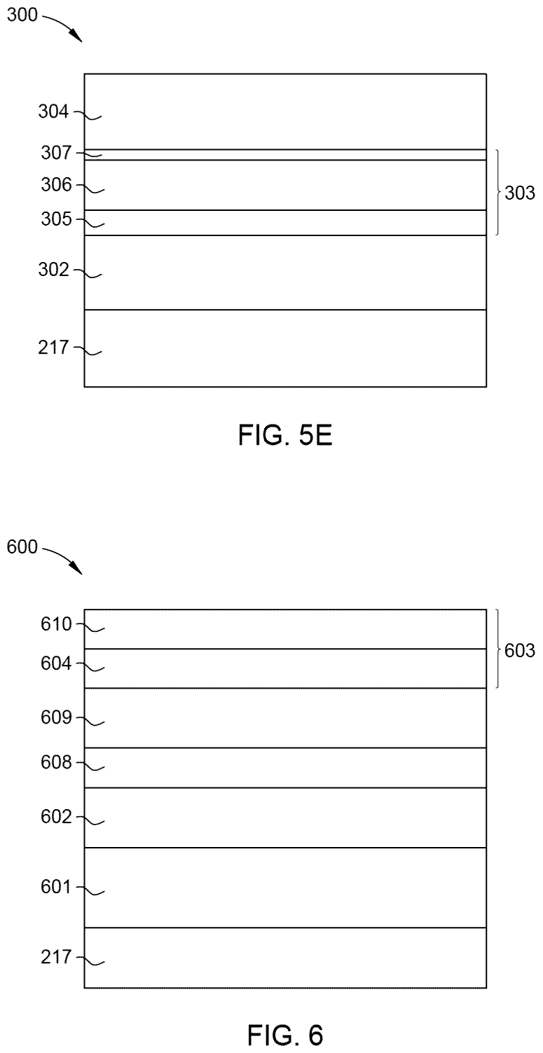

FIG. 4 is a flow diagram of a method of forming an optical device 300. FIGS. 5A-FIG. 5E are schematic, cross sectional views of a portion of an optical device 300 during a method 400 of forming the optical device 300.

At operations 401, a capping layer 302 is disposed over an illumination source 301, as shown in FIG. 5A. The capping layer 302 may include organic materials, such as Tris(8-hydroxyquinolinato)aluminium (ALq₃), a hole-transporting layer (HTLs), an electron injection layer (EILs), a hole injection layer (HIL), or combinations thereof. The illumination source may be disposed over a substrate 217.

At operation 402, a first atomic layer deposition (ALD) layer 305 is disposed over the capping layer 302, as shown in FIG. 5B. The first ALD layer 305 is deposited using ALD. In some embodiments, the first ALD layer 305 is deposited using plasma-enhanced ALD (PEALD). During the PEALD process, a substrate support 215 of the processing chamber 122 has temperature of about 60° C. to about 90° C. The pressure within the processing chamber 122 is maintained at about 650 mTorr to about 1550 mTorr during the PEALD process. The first power supply 212 provides about 500 W to about 1250 W of power during the PEALD process.

The PEALD process may use a plasma gas to initiate the plasma in the processing chamber. The plasma gas may include N₂, NH₃, H₂, He, Ar, or a combination thereof. The flow rate of the plasma gas is between 0 sccm and about 10000 sccm, e.g., N₂ may have a flow rate from about 0 sccm to about 10000 sccm, NH₃ may have a flow rate of about 0 sccm to about 1000 sccm, H₂ may have a flow rate of about 0 sccm to about 6000 sccm.

The PEALD process may use a purge gas to purge the processing chamber between deposition processes. The purge gas may include N₂, Ar, H₂, He, NH₃, or a combination thereof. The flow rate of the purge gas is between 5 sccm and about 120 sccm for about 5 second to about 10 seconds.

The PEALD process may use a precursor gas and a carrier gas to deposit the second ALD layer 307. The precursor gas may include trisilylamine (TSA), SiH₄, silicon, silicon nitride, or combinations thereof. The carrier gas may include Ar, H₂, N₂, He, or a combination thereof. The flow of the precursor gas during the PEALD process is from about 100 sccm to about 600 sccm for about 5 second to about 10 seconds.

At operation 403, a chemical vapor deposition (CVD) layer 306 is disposed over the first ALD layer 305, as shown in FIG. 5C. The CVD layer 306 is deposited using CVD. In some embodiments, the CVD layer 306 is deposited using plasma-enhanced CVD (PECVD). During the PECVD process, a substrate support 215 of the processing chamber 122 has temperature of about 60° C. to about 90° C. The pressure within the processing chamber 122 is maintained from about 600 mTorr to about 1050 mTorr during the PECVD process. The stress within the CVD layer 306 is from about −200 MPa to about 200 MPa.

The PECVD process may us a precursor gas to deposit the CVD layer 306. The precursor gas may include trisilylamine (TSA), SiH₄, silicon, silicon nitride, or combinations thereof. The flow of the precursor gas during the PECVD process is from about 100 sccm to about 600 sccm. The deposition rate of the PECVD process is about 2000 Å/min to about 3000 Å/min.

The PECVD process may use a plasma gas to initiate the plasma in the processing chamber. The plasma gas may include N₂, NH₃, H₂, Ar, He, or a combination thereof. The flow rate of the plasma gas is between 0 sccm and about 10000 sccm, e.g., N₂ may have a flow rate from about 0 sccm to about 10000 sccm, NH₃ may have a flow rate of about 0 sccm to about 1000 sccm, H₂ may have a flow rate of about 0 sccm to about 6000 sccm.

At operation 404, a second ALD layer 307 is disposed over the CVD layer 306, as shown in FIG. 5D. The first ALD layer 305, CVD layer 306, and second ALD layer 307 form an encapsulation layer 303. The second ALD layer 307 is deposited using ALD. In some embodiments, the second ALD layer 307 is deposited using PEALD. During the PEALD process, a substrate support 215 of the processing chamber 122 has temperature of about 60° C. to about 90° C. The pressure within the processing chamber 122 is maintained from about 650 mTorr to about 1550 mTorr during the PEALD process. The first power supply 212 provides about 500 W to about 1250 W of power during the PEALD process.

The PEALD process may use a plasma gas to initiate the plasma in the processing chamber. The plasma gas may include N₂, NH₃, H₂, Ar, He, or a combination thereof. The flow rate of the plasma gas is between 0 sccm and about 10000 sccm, e.g., N₂ may have a flow rate from about 0 sccm to about 10000 sccm, NH₃ may have a flow rate of about 0 sccm to about 1000 sccm, H₂ may have a flow rate of about 0 sccm to about 6000 sccm.

The PEALD process may use a purge gas to purge the processing chamber between deposition processes. The purge gas may include N₂, Ar, H₂, He, or a combination thereof. The flow rate of the purge gas is between 5 sccm and about 120 sccm for about 5 second to about 10 seconds.

The PEALD process may use a precursor gas and a carrier gas to deposit the second ALD layer 307. The precursor gas may include trisilylamine (TSA), SiH₄, silicon, and silicon nitride, or combinations thereof. The carrier gas may include Ar, H₂, He, N₂, or a combination thereof. The flow of the precursor gas during the PECVD process is from about 100 sccm to about 600 sccm for about 5 second to about 10 seconds.

Operations 402-404 may be performed within a single processing chamber 122. Performing the PEALD and PECVD processes in a single processing chamber 122 may increase the throughput of the optical devices 300. In some embodiments, the operations 402-404 may be repeated until the desired encapsulation layer 303 thickness is achieved.

At operation 405, a passivation layer 304 is disposed over the second ALD layer 307.

FIG. 6 is a schematic, cross sectional view of a flexible optical device 600. The flexible optical device 600 has a flexible encapsulation layer 603, an illumination source 601, a capping layer 602, a first passivation layer 608, and a polymer layer 609.

The flexible encapsulation layer 603 includes a second passivation layer 604 and an active matrix organic light emitting diode (AMOLED) layer 610. The AMOLED is configured to be an illumination source. The AMOLED layer 610 may be an on-cell touch AMOLED (e.g., a touch screen panel). The second passivation layer 604 may include a silicon nitride, a SiONₓ, SiOₓ, or a combination thereof. The AMOLED layer 610 includes a Tris(8-hydroxyquinolinato)aluminium (ALq₃), a hole-transporting layer (HTLs), an electron injection layer (EILs), a hole injection layer (HIL), or combination thereof. The flexible encapsulation layer 603 has a thickness of less than about 1 μm. The passivation layer 604 has a thickness of about 4000 Å to about 6000 Å. The AMOLED layer 610 has a thickness of about 1500 Å to about 2500 Å.

The reduction in the thickness of the flexible encapsulation layer 603 may reduce the color cross-talk of the illumination source 601, increasing the color definition of the optical device 600. The flexible encapsulation layer 603 has a refractive index greater than about 1.8, such as about 1.85 to 2.1. The high refractive index may reduce the layer to layer reflection, increasing the brightness of flexible optical device 600. The encapsulation layer 603 has an increased critical elongation (E_{cr}) requirement. An increase in the E_{cr} enables a reduction in the trend slope of defect size vs. time, indicating increased bendability while still maintaining the optical properties of the flexible optical device 600.

In summation, an optical device and method of making an optical device are disclosed. The optical device includes an encapsulation layer having a first atomic layer deposition (ALD) layer, a chemical vapor deposition (CVD) layer, and a second ALD layer. The CVD layer is disposed between the first and second ALD layers. The encapsulation layer has a thickness less than about 1 μm. The thickness and conformality of the encapsulation layer decreases the non-uniformity of the encapsulation layer by about 3% to about 5%. Further, the number of seamlines in the encapsulation layer is reduced. The reduction of seamlines results in a decrease in the water vapor transmission rate, increasing the ability of the encapsulation source to protect the illumination source from contaminants. The encapsulation layer further has stress of about −1000 MPa to about 300 MPa. The difference in stress (Δ Stress) is less than about 50 MPa from the center of the substrate to the edge of the substrate.

While the foregoing is directed to examples of the present disclosure, other and further examples of the disclosure may be devised without departing from the basic scope thereof, and the scope thereof is determined by the claims that follow.

What is claimed is:

1. An optical device, comprising:
a substrate;
an illumination source;
a capping layer;
an encapsulation layer, comprising:
a first atomic layer deposition (ALD) layer;
a chemical vapor deposition (CVD) layer; and
a second ALD layer; and
a passivation layer.

2. The optical device of claim 1, wherein the encapsulation layer has a refractive index greater than about 1.85.

3. The optical device of claim 1, wherein the encapsulation layer has a refractive index of about 1.85 to about 2.1.

4. The optical device of claim 1, wherein the optical device has a water vapor transmission rate (WVTR) less than about 5×10⁻⁵ g/m²/day.

5. The optical device of claim 1, wherein a difference in stress (Δ Stress) from a center of the substrate to an edge of the substrate is less than about 50 MPa.

6. The optical device of claim 1, wherein the encapsulation layer has stress of about −1000 MPa to about 300 MPa.

7. The optical device of claim 1, wherein the first ALD layer has a thickness of less than about 50 Å.

8. The optical device of claim 1, wherein the CVD layer has a thickness of less than about 1 μm.

9. The optical device of claim 1, wherein the second ALD layer has a thickness of less than about 10 Å.

10. A method of forming an optical device, comprising:
disposing a capping layer over an illumination layer, the illumination layer disposed over a substrate, in a processing chamber;
disposing a first atomic layer deposition (ALD) layer over the capping layer;
disposing a chemical vapor deposition (CVD) layer over the first ALD layer;
disposing a second ALD layer over the CVD layer; and
disposing a passivation layer over the second ALD layer.

11. The method of claim 10, wherein a substrate support of the processing chamber has temperature of about 60° C. to about 90° C.

12. The method of claim 10, wherein disposing the first ALD layer over the capping layer and disposing the second ALD layer over the CVD layer are performed while the processing chamber has a pressure of about 650 mTorr to about 1550 mTorr.

13. The method of claim 10, wherein disposing the CVD layer over the first ALD layer is performed while the processing chamber has a pressure of about 650 mTorr to about 1050 mTorr.

14. The method of claim 10, wherein disposing the CVD layer over the first ALD layer is performed at a deposition rate of about 2000 Å/min to about 3000 Å/min.

15. The method of claim 10, wherein the disposing of the first ALD layer, the CVD layer, and the second ALD layer includes flowing a precursor gas comprising trisilylamine (TSA), SiH₄, silicon, silicon nitride, or combinations thereof.

16. An optical device, comprising:
a substrate;
an illumination source;
a capping layer;
a first passivation layer;
a polymer layer; and
an encapsulation layer, comprising:
a second passivation layer; and
an active matrix organic light emitting diode (AMOLED) layer.

17. The optical device of claim 16, wherein the encapsulation layer has a refractive index of about 1.85 to about 2.1.

18. The optical device of claim 16, wherein the encapsulation layer has a water vapor transmission rate (WVTR) less than about 5×10⁻⁵ g/m²/day.

19. The optical device of claim 16, wherein a difference in stress (Δ Stress) from a center of the substrate to an edge of the substrate is less than about 50 MPa.

20. The optical device of claim 16, wherein the encapsulation layer has stress of about −1000 MPa to about 300 MPa.
